(19) United States
(12) Patent Application Publication
(10) Pub. No.: US 2020/0395526 A1
(43) Pub. Date: Dec. 17, 2020

(54) MAGNETIC THERMOELECTRIC CONVERSION ELEMENT AND THERMOELECTRIC CONVERSION SYSTEM INCLUDING SAME

(71) Applicants: NEC CORPORATION, Tokyo (JP); TOHOKU UNIVERSITY, Sendai-Shi, Miyagi (JP)

(72) Inventors: Masahiko ISHIDA, Tokyo (JP); Akihiro KIRIHARA, Tokyo (JP); Ryohto SAWADA, Tokyo (JP); Eiji SAITOH, Sendai-shi (JP); Ryo IGUCHI, Sendai-shi (JP); Yasuyuki OIKAWA, Sendai-shi (JP); Masao ONO, Naka-gun (JP)

(73) Assignees: NEC CORPORATION, Tokyo (JP); TOHOKU UNIVERSITY, Sendai-shi, Miyagi (JP)

(21) Appl. No.: 16/771,869

(22) PCT Filed: Nov. 21, 2018
(86) PCT No.: PCT/JP2018/042971

§ 371 Date: Jun. 11, 2020

(30) Foreign Application Priority Data
Dec. 12, 2017 (JP) 2017-237459

(51) Int. Cl. H01L 37/04; F02C 7/12

(52) U.S. Cl. CPC H01L 37/04; F02C 7/12

(57) ABSTRACT

To protect the surface of a member exposed to a high-temperature environment and detect surface temperature or heat flow distribution, this magnetic thermoelectric conversion element, which is provided on the surface of a support in contact with a heat source, has: a magnetic body; an electromotive body which is magnetically coupled to the magnetic body and has electrical conductivity; and a heat-resistant metal oxide film covering the magnetic body and the electromotive body.

### TECHNICAL FIELD

The present invention relates to a protection film for a surface of a member and, more particularly, to a magnetic thermoelectric conversion element and a thermoelectric conversion system including the same, which are capable of protecting the surface of the member exposed to a high-temperature environment and of detecting a temperature of the surface or heat flow distribution.

### BACKGROUND ART

With increase of energy demand in recent years, high efficiency has been desired in various power-driven machines. In an internal combustion engine such as a combustion gas turbine and a jet engine and an external combustion engine such as a steam turbine, increase in operation temperature and improvement of durability thereof are desired toward the high efficiency.

Patent Literature 1 discloses a gas turbine combustor. In the gas turbine combustor disclosed in Patent Literature 1, an annular housing is defined by an outer casing and an inner casing, and an annular combustion tube is defined by an outer liner and an inner liner in the interior thereof. An annular inner space is formed in the interior of the combustion tube and this inner space serves as a combustion chamber. A plurality of fuel injection devices for injecting a fuel to the interior of the combustion chamber are arranged at equal intervals in a circumferential direction thereof. Each fuel injection device includes a fuel injector valve (fuel injection nozzle) for injecting the fuel and a main swirler of a radial flow type. Ignition plugs (ignition devices) are disposed in the combustor.

Patent Literature 2 discloses a turbofan engine which is one example of gas turbine engines. The turbofan engine comprises a fan cowl, a core cowl, a fan, a low-pressure compressor, a high-pressure compressor, a combustor, a high-pressure turbine, a low-pressure turbine, a shaft, and a main nozzle. The combustor is arranged at the downstream of the high-pressure compressor, and generates a combustion gas by burning an air-fuel mixture consisting of compressed air sent from the high-pressure compressor and a fuel supplied from an injector (fuel injection nozzle). The high-pressure turbine is arranged at the downstream of the combustor and recovers rotative power from the combustion gas discharged from the combustor to drive the high-pressure compressor. The high-pressure turbine comprises a plurality of turbine rotor vanes which are fixed to the shaft, a plurality of turbine stator vanes which are fixed to a core passage, and shrouds. The shrouds, which are provided facing the tip of the turbine rotor vanes, form a portion of the passage of the combustion gas discharged from the combustor. The shroud is equipped with a groove portion which is provided in the surface facing the turbine rotor vanes (combustion gas passage surface), and a plurality of film cooling holes that open to a bottom portion of the groove portion.

In the combustion gas turbine and the jet engine, the combustor normally has an internal temperature which is not lower than 1,000° C. As a heat-resistant material used under this environment, an alloy which keeps a heat-resistant temperature of about 1,000° C., such as a Ni-based superalloy, is used. On the other hand, in the steam turbine used in thermal power generation and so on, high-temperature steam has a temperature of 600° C. to 800° C. In the steam turbine up to about 600° C., ferrite-based heat-resistant steel is used for the reason of economic efficiency. In the steam turbine exceeding 600° C., austenite-based heat-resistant steel, which is a heat-resistant alloy exceeding the ferrite-based one, is used.

In the power-driven machines such as the internal combustion engine and the external combustion engine, increase in operation temperature is advancing for the purpose of achieving the high efficiency thereof. The operation temperature already exceeds a melting point of a base material of the heat-resistant alloy members such as the turbine rotor vanes and the turbine stator vanes, and various cooling techniques are adopted. A temperature difference exceeding the heat-resistant temperature of the base material, the base material is effectively cooled by means of film cooling by air (e.g., see the above-mentioned Patent Literature 2) or a thermal barrier coating which will later be described. The thermal barrier coating (TBC) film actualizes a heat-shielding effect of about 150° C. The thermal barrier coating is also called a heat-shielding coating.

Normally, the TBC film has a two-layer structure which comprises a top coat having a low thermal conductivity and a bond coat for preventing oxidation of the base material. As the top coat, generally, a ceramic is used, such as yttria (Y₂O₃) or stabilized zirconium oxide (YSZ). As the bond coat, a Pt—Al alloy made of an aluminum diffusion coating on the base material or the like is used.

For example, Patent Literature 3 discloses a heat-shielding coating material that exhibits superior high-temperature crystal stability to YSZ, as well as a high degree of toughness and an excellent thermal barrier effect.

Various types of thermal barrier coatings may cause cracks to be separated because of continuous thermal stress load or degeneration of an interface. Such a separation of the thermal barrier coatings may possibly cause an apparatus to be locally heated to result in a serious accident. If operation of the apparatus stops due to such a serious accident, this results in a large loss of an opportunity cost. Therefore, in order to prevent such an accident before it occurs, temperature monitoring of members of the apparatus is carried out.

For example, Patent Literature 4 discloses a “boiler monitoring device” for monitoring an exhaust gas which is generated from a combustion furnace of a boiler. The boiler comprises a monitoring probe (monitoring device) which is brought into contact with the exhaust gas in order to monitor adhesion of a deposit. The probe comprises an outer cylinder which is brought into contact with the exhaust gas, an inner cylinder which is concentrically disposed inside the outer cylinder, and a water feeding pipe which is disposed further inside the inner cylinder. Eight thermoelectric transducing elements are arranged in an annular gap formed between the outer cylinder and the inner cylinder at regular intervals throughout an entire circumference. Each thermoelectric transducing element detects a temperature difference between a high-temperature-side thermal sensitive section and a low-temperature-side thermal sensitive section. The high-temperature-side thermal sensitive section is in contact with an inner wall surface of the outer cylinder whereas the low-temperature-side thermal sensitive section is in contact with an outer wall surface of the inner cylinder. The thermoelectric transducing device having such a configuration is called a “Seebeck element” or the like. Upon occurrence of the temperature difference between the high-temperature-side thermal sensitive section and the low-temperature-side thermal sensitive section, a potential difference is generated between two terminal electrodes constituting the low-temperature-side thermal sensitive section, and an electric current corresponding to the temperature difference flows in an electric current detection portion which is connected to the terminal electrodes.

Patent Literature 5 discloses a gas turbine monitoring device for monitoring unusual heat generation in a gas turbine combustor. The gas turbine combustor is configured so that an outer cylinder and a combustor liner barrel for forming a combustor chamber are inserted in a gas turbine casing. The combustor liner barrel is made of metal or ceramics. The combustor liner barrel has a head portion on which a fuel nozzle (fuel injection nozzle) is assembled and a fuel is injected from the fuel nozzle (fuel injection nozzle) into the combustion chamber to be burnt. Between the outer barrel and the combustor liner barrel, an annular passage for circulating combustion air blown out from a gas turbine compressor toward the combustion chamber in the combustor liner barrel is formed. The gas turbine monitoring device disclosed in Patent Literature 5 comprises an infrared radiation temperature detector which receives infrared radiation emitted from an outer surface of the combustor liner barrel of the gas turbine combustor during combustion and detects a surface temperature distribution of the combustor liner barrel. The infrared radiation temperature detector is installed to a flange portion on an outer portion of the gas turbine casing at a position corresponding to a high-temperature area of the combustor liner barrel of the gas turbine combustor. In addition, Patent Literature 5 describes that the combustor liner barrel adopts film cooling of introducing air through a plurality of holes (cooling holes) or the like.

Patent Literature 6 discloses a method of detecting defects in a combustion duct of a combustion system of a combustion turbine engine while the turbine engine operates. A combustor, which may be used in a gas turbine engine, includes fuel nozzles or fuel injectors. The fuel injectors bring together a mixture of fuel and air for combustion. Downstream of the fuel injectors is a combustion chamber in which the combustion occurs. The combustion chamber is generally defined by a liner, which is enclosed within a flow sleeve. Between the flow sleeve and the liner an annulus is formed. From the liner, a transition piece transitions the flow from a circular cross section of the liner to an annular cross section as it travels downstream to a turbine section. An interior wall surface of the transition piece may be coated with an insulator coating. The insulator coating may comprise a thermal barrier coating. A zirconia oxide thermal barrier coating may be used in certain preferred environments. A first electrode may be electrically connected to the transition piece. The transition piece may be metallic and have a high electrical conductivity. A second electrode may be positioned such that it is electrically exposed to a hot-gas path (and not connected to the transition piece). The second electrode passes through the transition piece but is electrically insulated from the transition piece by an electrically insulating material or structure, while also having a conducting tip that is exposed to the hot-gas flow path. The second electrode may be positioned, at least in part, such that it is exposed to the hot-gas flow path and in proximity to the first electrode.

Furthermore, there is an attempt to make the thermal barrier coating itself have this temperature monitoring function. For example, Patent Literature 7 describes that a monocrystalline ZnO film is formed as an underlying base of a thermal barrier coating of a combustion gas turbine so as to function as a heat flow sensor. By forming the monocrystalline ZnO film in such a way that a c axis thereof is tilted relative to a gas turbine surface, heat flow in a direction perpendicular to the gas turbine surface is detected by means of an anisotropic thermoelectric transducing property of ZnO.

### CITATION LIST

### Patent Literature(s)

PTL 1: WO 2011/092779

PTL 2: WO 2013/129530

PTL 3: WO 2010/116568

PTL 4: JP 2008-261747 A

PTL 5: JP 3857420 B

PTL 6: JP 2012-145101 A

PTL 7: JP 2016-500780 A

### SUMMARY OF INVENTION

### Technical Problem

As described above, it is necessary to install a thermometer in an interior if it is desired to carry out temperature monitoring of the member used under the high-temperature environment.

However, in local temperature measurement as described in Patent Literature 4, an accurate temperature distribution of the member is not known and a sufficient monitoring performance cannot be exhibited. In other words, such a measurement only measures a local temperature and is difficult to detect abnormality of the apparatus. In addition, if it is desired to detect temperatures at a plurality of spots, the number of the thermometers is increased to bring about a remarkable increase in cost. Furthermore, installation of the thermometer under the high-temperature environment causes another restriction such as life of the thermometer as well as life of the thermal barrier coating. In such a case where the thermometer is broken before the thermal barrier coating, the apparatus must be frequently stopped to increase loss of opportunity.

In Patent Literature 5, the infrared radiation temperature detector merely receives the infrared radiation emitted from a specific area (high-temperature area) of the combustor liner barrel and detects the surface temperature distribution of the specific area. Accordingly, in Patent Literature 5, it is not possible to detect the surface temperature distribution over a whole of the combustor liner barrel.

In Patent Literature 6, loss or deterioration of the thermal barrier coating on the surface of the member is detected through conduction of the surface thereof. However, such a detection method notifies occurrence of the loss of the coating, but cannot teach an appropriate operation while judging a status of a thermal load.

On the other hand, forming the monocrystalline film made of a specific material, as in Patent Literature 7, has a problem in view of cost and yield. Specifically, in an application to a large-area member such as the turbine, to make a uniform monocrystalline film remarkably increases a manufacturing cost.

It is an object of this invention to provide a magnetic thermoelectric conversion element and a thermoelectric conversion system including the same, which are capable of protecting a surface of a member exposed to a high-temperature environment and of detecting a temperature of the surface and a heat flow distribution.

### Solution to Problem

A magnetic thermoelectric conversion element according to an aspect of this invention is provided on a surface of a support in contact with a heat source and comprises a magnetic body; an electromotive body which is magnetically coupled to the magnetic body and which has an electrical conductivity; and a heat-resistant metal oxide film configured to cover the magnetic body and the electromotive body.

A thermoelectric conversion system according to another aspect of this invention is provided on a surface of a support in contact with a heat source and comprises at least one magnetic thermoelectric conversion element which is disposed at a predetermined position of the support, the magnetic thermoelectric conversion element comprising a magnetic body and an electromotive body which is magnetically coupled to the magnetic body; and a means configured to collect, via wirings electrically connected to the electromotive body, electrical signals which are obtained by thermoelectric conversion, wherein the magnetic thermoelectric conversion element and the wirings are covered by a heat-resistant metal oxide film.

### Advantageous Effect of Invention

According to this invention, it is possible to protect a surface of a member exposed to a high-temperature environment and to detect a temperature of the surface and a heat flow distribution.

### BRIEF DESCRIPTION OF THE DRAWINGS

FIG. 1 is a schematic view for illustrating an example of a gas turbine combustor according to a related art;

FIG. 2 is a fragmentary schematic cross-sectional view for illustrating a magnetic thermoelectric conversion element according to a first example embodiment of the present invention;

FIG. 3 is a fragmentary schematic cross-sectional view for illustrating a magnetic thermoelectric conversion element according to a second example embodiment of the present invention;

FIG. 4 is a view for illustrating a schematic configuration of a gas turbine combustor to which a thermoelectric conversion system according to a third example embodiment of the present invention is applicable;

FIG. 5 is a fragmentary enlarged view for illustrating a portion enclosed by a rectangle A in FIG. 4 in an enlarged state;

FIG. 6 is a plan view for illustrating a schematic configuration of a temperature distribution detection device according to a first example of the present invention;

FIG. 7A is a fragmentary cross-sectional view for illustrating a schematic configuration of a temperature distribution detection device according to a second example of the present invention;

FIG. 7B is a schematic plan view for illustrating the schematic configuration of the temperature distribution detection device according to the second example of the present invention;

FIG. 7C is a fragmentary cross-sectional view for illustrating the schematic configuration of the temperature distribution detection device according to the second example of the present invention;

FIG. 8A is a schematic perspective view for illustrating a schematic configuration of a temperature distribution detection device according to a third example of the present invention; and

FIG. 8B is a cross-sectional view for illustrating the schematic configuration of the temperature distribution detection device according to the third example of the present invention.

### DESCRIPTION OF EMBODIMENTS

### Related Art

In order to facilitate an understanding of this invention, a combustor to which the present invention is applicable will be described.

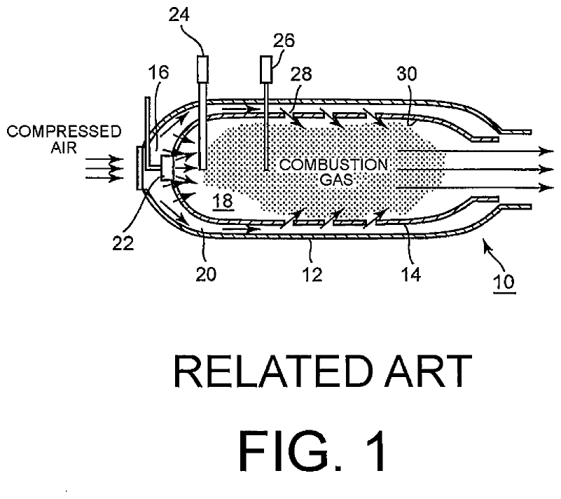

FIG. 1 is a schematic view for illustrating an example of a combustor 10 according to a related art, to which the present invention is applicable. The combustor 10 illustrated in the figure is a gas turbine combustor. The gas turbine combustor 10 comprises an annular housing (outer barrel) 12 and an annular combustion tube (combustor liner barrel) 14 which is formed in the interior of the annular housing (outer barrel) 12. The housing 12 is also called a casing.

In the gas turbine combustor 10, compressed air (combustion air) fed from a compressor which is not shown in the figure is introduced into an annular internal space of the housing (outer barrel) 12 through an annular diffuser 16.

In other words, between the outer barrel 12 and the combustor liner barrel 14, an annular passage 20 for circulating the combustion air blown out from the compressor toward a combustion chamber 18 in the combustor liner barrel 14 is formed.

The combustor liner barrel 14 has a head portion on which a combustion injection nozzle 22 is assembled, and a fuel is injected from the combustion injection nozzle 22 into the combustion chamber 18 to be burnt.

At a predetermined spot of the combustor 10 (at a position close to the fuel injection nozzle 22 in the example being illustrated), an ignition device 24 is disposed. In addition, at a different predetermined spot of the combustor 10, a thermometer 26 for measuring a temperature in the combustion chamber 18 is also provided. As the thermometer 26, an item using a thermocouple is used. Furthermore, in the combustor liner barrel 14, a plurality of cooling holes 28 passing through between the annular passage 20 and the combustion chamber 18 are formed. Accordingly, the illustrated combustor liner barrel 14 adopts film cooling of introducing air through the plurality of cooling holes 28.

As described above, the illustrated combustor 10 is a constituent part for burning the fuel such as kerosene or a jet fuel while it is continuously jetted from the combustion injection nozzle 22 and mixed with the compressed air, thereby expanding its volume, so as to use an obtained combustion gas having a high flow rate in driving a runner (not shown) or in a jet mechanism (not shown).

In order to obtain higher efficiency, combustion at a higher temperature is desired. Therefore, in the combustor liner barrel 14, a member provided with a heat-resistant coat 30 applied on an inner wall surface thereof is used. As mentioned above, as the heat-resistant coat 30, the TBC film or the thermal heat-shielding coating as disclosed in Patent Literature 3 is used.

The combustor 10 having such a configuration is mainly used in continuous operation of the gas turbine, the jet engine, or the like. Accordingly, if it is possible to detect local unusual combustion due to clogging of the cooling holes 28 or deterioration of the heat-resistant coat 30 during operation, securement of further safety can be expected.

In the related art, a combustion state has been judged by temperature measurement by means of the thermometer 26 mainly using the thermocouple. Such a measurement cannot detect local abnormality.

In addition, it is conceivable to use, as the thermometer 26, the infrared radiation temperature detector disclosed in the above-mentioned Patent Literature 5. As described above, however, this method cannot detect the surface temperature distribution over the whole of the combustor liner barrel 14.

Further, it is conceivable to detect loss or deterioration of the thermal barrier coating 30 on the surface of the member through conduction of the surface thereof, as in the above-mentioned Patent Literature 6. As described above, however, such a detection method merely notifies occurrence of the loss in the thermal barrier coating 30, but cannot teach an appropriate operation while judging a status of a thermal load.

Furthermore, in order to make the thermal barrier coating 30 itself have this temperature monitoring function, it is conceivable to form a monocrystalline ZnO film as an underlying base of the thermal barrier coating 30, as in the above-mentioned Patent Literature 7. As described above, however, forming the monocrystalline film made of a specific material has a problem in view of cost and yield. Specifically, in application to a large-area member such as the turbine, to make a uniform monocrystalline film remarkably increases a manufacturing cost.

[Outline of Invention]

The present invention provides a hot-gas path member which is suitable for an environment, where a hot gas (combustion gas) flows, in the gas turbine combustor 10 (see FIG. 1) or the like. The hot-gas path member comprises, at an outer surface thereof, a spin Seebeck structure which comprises a two-layer film consisting of a magnetic layer and a metal layer. The spin Seebeck structure generates a voltage proportional to a temperature difference between an inner surface being in contact with the hot gas and an outer surface being in contact with a cooling flow. By reading the voltage using a measurement wire disposed along the outer surface, it is possible to measure a temperature distribution of the outer surface of the member without obstructing a stream of the hot gas or the cooling flow.

It is preferable that the spin Seebeck structure is formed so as to cover the surface of the hot-gas path member as much as possible. Specifically, it is preferable that a plurality of metal layers are formed on the magnetic layer to make it possible to detect the temperature distribution substantially over the whole of the surface of the gas path member. In particular, a spin Seebeck voltage is proportional to the temperature difference, and therefore a large thermal load is applied at a spot where an output is large. Accordingly, it is possible to take measures to decrease this load and to prolong life of the hot-gas path member.

### First Example Embodiment

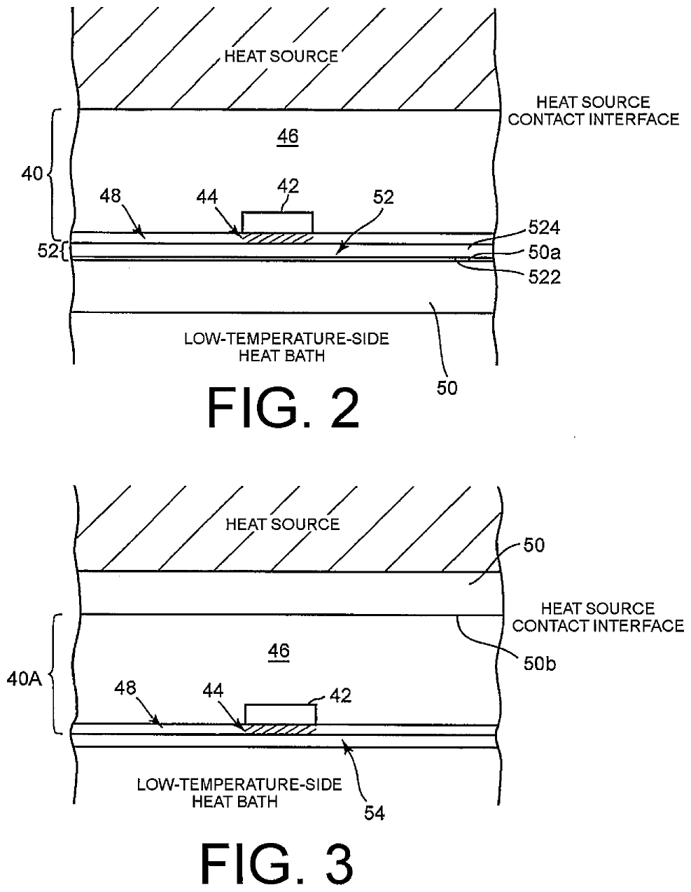

Referring to FIG. 2, description will proceed to a magnetic thermoelectric conversion element 40 according to a first example embodiment of the present invention. The illustrated magnetic thermoelectric conversion element 40 is an element in a case where it is disposed in direct contact with a heat source side. Herein, the heat source corresponds to, for example, the combustion gas in a case of an example in FIG. 1.

The magnetic thermoelectric conversion element 40 is disposed on a first surface 50a of a support 50. Herein, the support 50 corresponds to, for example, the combustion liner barrel 14 in a case of the example in FIG. 1. Accordingly, the first surface 50a of the support 50 corresponds to the inner wall surface of the combustion liner barrel 14 in FIG. 1.

The support 50 is made of a general metal base material which may be appropriately selected in accordance with a use of the member. For instance, the metal base material is exemplified by high chromium ferrite steel, austenite steel, a Ni-based superalloy, or the like.

The magnetic thermoelectric conversion element 40 is in close contact with the first surface 50a of the support 50 via a contact layer 52.

The contact layer 52 comprises a diffused layer 522 and a bonding layer 524.

The bonding layer 524 is formed by metal coating to the support 50 together with the diffused layer 522 for the purpose of oxidation resistance. The bonding layer 524 typically has a thickness of 75 μm to 150 μm. Specifically, the bonding layer 524 is exemplified by an aluminum diffused coating or the like. Furthermore, in a case where corrosion resistance and the oxidation resistance are desired, the bonding layer 524 may be formed by plasma-spraying MCrAlY (M=Ni, Co) or the like.

Accordingly, in the first example embodiment, a combination of the support 50, the contact layer 52, and the magnetic thermoelectric conversion element 40 constitutes the hot-gas path member (50, 52, 40).

The magnetic thermoelectric conversion element 40 includes a magnetic body 42, an electromotive body 44, and a heat-resistant metal oxide film 46. The electromotive body 44 is magnetically coupled to the magnetic body 42 and has electrical conductivity. Wirings 48 are connected to the electromotive body 44. The heat-resistant metal oxide film 46 covers the magnetic body 42, the electromotive body 44, and the wirings 48.

The heat-resistant metal oxide film 46 comprises a ceramic coating for the purpose of a thermal barrier effect and is exemplified by, as a most general material, a sprayed film of yttria stabilized zirconia or an electron beam evaporation film. The heat-resistant metal oxide film 46 typically has a thickness of 100 μm to 1,000 μm.

The heat-resistant metal oxide film 46 preferably has a thermal conductivity which is not more than 10 [W/mK] and more preferably has a thermal conductivity which is not more than 1 [W/mK]. In addition, the heat-resistant metal oxide film 46 preferably has a heat-transfer coefficient which is not more than 10⁴ [W/m²K]. In other words, the heat-resistant metal oxide film 46 is required to have a thickness of 1,000 μm or more if the thermal conductivity thereof is 10 [W/mK] whereas the heat-resistant metal oxide film 46 is required to have a thickness of 100 μm or more if the thermal conductivity thereof is 1 [W/mK].

In the example being illustrated, the magnetic body 42 comprises a magnetic insulator layer. A material for forming the magnetic insulator layer 42 is not particularly limited but is exemplified by garnet ferrite, spinel ferrite, hexaferrite, perovskite, corundum, a ferromagnetic material of a rutile-type or the like, an antiferromagnetic material, and a ferrimagnetic material. The magnetic body 42 typically has a thickness of 10 nm to 4,000 nm.

In the example being illustrated, the electromotive body 44 comprises a metal layer. The metal layer 44 is electrically insulated from the bonding layer 524. A material for forming the metal layer 44 is not particularly limited, so long as it is a metal exhibiting a spin orbit interaction sufficient to generate an inverse spin Hall effect. By way of example, the metal layer 44 is exemplified by a simple metal, such as Pt, Au, Ir, Pd, Ni, W, Ta, Mo, Nb, Cr, or Ti, a binary alloy, such as NiFe, FePt, IrMn, or AuCu, a metal two-layer film, such as Pt/Cu, Pt/Au, Pt/FeCu, Pt/Ti, CoFeB/Ti or Co/Cu, and a conductive oxide, such as IrO₂ or SrRuO₃. In addition, the metal layer 44 may be a magnetic metal. For instance, the magnetic metal is exemplified by Permalloy as a magnetic alloy. The metal layer 44 typically has a thickness of 10 nm to 1000 nm.

A guideline for giving a typical combination of materials is exemplified by a Curie temperature of the magnetic insulator layer (magnetic body) 42, a melting point of the metal layer (electromotive body) 44, and differences in thermal expansion coefficient among four layers including the bonding layer 524, the magnetic insulator layer (magnetic body) 42, the metal layer (electromotive body) 44, and the heat-resistant oxide film 46.

The higher a Curie point of the magnetic insulator layer (magnetic body) 42 is, it is more suitable for use in the high-temperature environment. For instance, magnetite (Fe₃O₄) has a Curie point of 585° C., nickel ferrite (NiFe₃O₄) has a Curie point of 590° C., and cobalt ferrite (CoFe₂O₄) has a Curie point of 520° C. These substances have a high Curie point among ferrites.

The higher a melting point of the metal layer (electromotive body) 44 is, it is more suitable for use in the high-temperature environment. For instance, platinum (Pt) has a melting point of 3,800° C. and tungsten (W) has a melting point of 3,400° C. Such simple metals are stable under a high temperature.

It is preferable that the differences in thermal expansion coefficient among the four layers including the bonding layer 524, the magnetic insulator layer (magnetic body) 42, the metal layer (electromotive body) 44, and the heat-resistant metal oxide film 46 fall within a range of 1×10⁻⁸ to 1×10⁻⁴. As one example, it is assumed that the bonding layer 524 comprises an NiCrAlY alloy or an NiCoCrAlY alloy (thermal expansion coefficient of 14×10⁻⁶K⁻¹), the heat-resistance metal oxide film 46 comprises yttria stabilized zirconia (thermal expansion coefficient of 10.5×10⁻⁶K⁻¹), the metal layer (electromotive body) 44 comprises platinum (thermal expansion coefficient of 8.8×10⁻⁶K⁻¹), and the magnetic insulator layer (magnetic body) 42 comprises magnetite (thermal expansion coefficient of 1.3×10⁻⁵K⁻¹). Then, the combination thereof is included in suitable combinations of thermal expansion coefficients.

The wirings 48 comprise a metal layer. A material for forming the wirings 48 is not particularly limited but may be a material which is identical to that of the metal layer (electromotive body) 44. For instance, if the metal layer (electromotive body) 44 is formed of platinum (Pt), the wirings 48 also may be formed of platinum (Pt). If the metal layer (electromotive body) 44 and the wirings 48 are formed of the same material as mentioned above, there is an advantage that a manufacturing process can be simplified, etc.

A combination of the magnetic insulator layer (magnetic body) 42 and the metal layer (magnetic body) 44 constitutes a function layer (42, 44). The function layer (42, 44) constitutes a spin Seebeck element.

In the hot-gas path member (50, 52, 40), a temperature difference is generated between a temperature on the side of the heat-resistant metal oxide film 46 and a temperature of the opposite side (low-temperature side heat bath) during use thereof. The temperature difference is distributed by thermal resistances of respective layers in the coating, and then a temperature difference is also generated in the magnetic insulator layer (magnetic body) 42. Due to the temperature difference, a spin current is generated in the magnetic insulator layer (magnetic body) 42. The metal layer (electromotive body) 44 generates a voltage due to the inverse spin Hall effect caused by the spin current flowing from the magnetic insulator layer (magnetic body) 42. This voltage is called a spin Seebeck voltage. The spin Seebeck voltage is also called a spin Seebeck electromotive force.

Inasmuch as the spin Seebeck voltage is proportional to the temperature difference generated in the magnetic insulator layer (magnetic body) 42, it is possible to measure the temperature difference generated in the hot-gas path member (50, 52, 40) due to the spin Seebeck voltage. In addition, if the metal layer (electromotive body) 44 comprises the magnetic metal, an anomalous Nernst voltage proportional to the temperature difference is generated. In this case, it is possible to detect the temperature difference by calculating a sum of the spin Seebeck voltage and the anomalous Nernst voltage. In addition, in order to exhibit the spin Seebeck effect and the anomalous Nernst effect, the magnetic insulator layer (magnetic body) 42 is required to be magnetized in one direction.

As described above, the magnetic thermoelectric conversion element 40 according to the first example embodiment is disposed on the inner wall surface (first surface) 50a of the support 50. Therefore, as shown in FIG. 2, the heat-resistant metal oxide film 46 has a heat source contact interface which is in contact with the above-mentioned heat source kept at or above a temperature (Curie temperature) at which the magnetic body 42 loses magnetism.

### First Modification

Referring now to FIG. 2, description will proceed to the magnetic thermoelectric conversion element 40 according to a first modification of the present invention.

Although the magnetic thermoelectric conversion element 40 according to the first modification has a configuration which is similar to that of the magnetic thermoelectric conversion element 40 according to the above-mentioned first example embodiment, the function layer (42, 44) and the bonding layer 524 have different compositions (materials), as will later be described. Hereinafter, in order to simplify the description, only a difference from the first example embodiment will be described.

The difference from the first example embodiment is that the magnetic body 42 of the function layer (42, 44) comprises a magnetic metal layer in the first modification. As an example of such a magnetic metal layer 42, Permalloy as a magnetic alloy or the like is cited.

In this case, the bonding layer 524 preferably comprises alumina, which is an electrical insulator, or the like so that the voltage generated by the function layer (42, 44) never leaks to the support 50 through the bonding layer 524. Alternatively, a thin electrical insulation layer may be formed on the bonding layer 524.

### Second Example Embodiment

Referring to FIG. 3, description will proceed to a magnetic thermoelectric conversion element 40A according to a second example embodiment of the present invention. The illustrated magnetic thermoelectric conversion element 40A is an element in a case where it is brought into contact with a heat source via the support 50. Herein, the heat source corresponds to, for example, the combustion gas in a case of the example in FIG. 1.

The illustrated magnetic thermoelectric conversion element 40A is disposed on a second surface 50b of the support 50. Herein, the support 50 corresponds to, for example, the combustion liner barrel 14 in a case of the example in FIG. 1. Accordingly, the second surface 50b of the support 50 corresponds to the outer wall surface of the combustion liner barrel 14 in FIG. 1.

The magnetic thermoelectric conversion element 40A is directly in close contact onto the second surface 50b of the support 50.

The illustrated magnetic thermoelectric conversion element 40A is similar in structure to the magnetic thermoelectric conversion element 40 illustrated in FIG. 2. A difference from the first example embodiment is an arrangement only.

Specifically, in the first example embodiment, the heat-resistant metal oxide film 46 is directly in contact with the heat source. In contrast to this, in the second example embodiment, the heat-resistant metal oxide film 46 is in contact with the heat source via the support 50.

In addition, in the second example embodiment, a surface protection layer 54 is provided instead of the contact layer 52.

Accordingly, in the second example embodiment, a combination of the support 50, the surface protection layer 54, and the magnetic thermoelectric conversion element 40A constitutes the hot-gas path member (50, 54, 40A).

As described above, the magnetic thermoelectric conversion element 40A according to the second example embodiment is provided on the outer wall surface (second surface) 50b of the support 50. Therefore, as shown in FIG. 3, the heat-resistant metal oxide film 46 has a heat source contact interface which is in contact, via the support 50, with the above-mentioned heat source kept at or above a temperature (Curie temperature) at which the magnetic body 42 loses magnetism.

In other words, the illustrated hot-gas path member (50, 54, 40A) has an inner surface which is in contact with the hot gas and an outer surface which is in contact with the cooling flow. The hot-gas path member (50, 54, 40A) comprises a magnetic layer (42) formed on the outer surface, the metal layer (44) which is in contact with the cooling flow with the magnetic layer (42) overlapped thereon, and measurement wires (48) which are disposed from the metal layer (44) along the outer surface.

Inasmuch as a temperature detection principle of the hot-gas path member (50, 54, 40A) is identical with that of the above-mentioned hot-gas path member (50, 52, 40), the description thereof is omitted.

### Third Example Embodiment

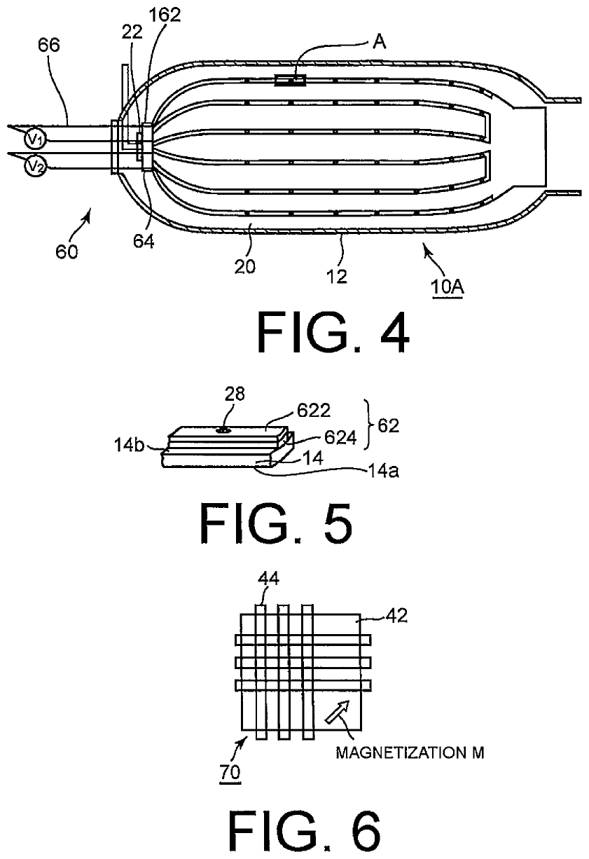

Referring to FIGS. 4 and 5, description will proceed to a thermoelectric conversion system 60 according to a third example embodiment of the present invention.

FIG. 4 is a view for illustrating a schematic configuration of a gas turbine combustor 10A to which the thermoelectric conversion system 60 according to the third example embodiment of the present invention is applicable. FIG. 5 is a fragmentary enlarged view in which a portion enclosed by a rectangle A in FIG. 4 is illustrated in an enlarged state.

The illustrated gas turbine combustor 10A is similar in structure and operation to the gas turbine combustor 10 illustrated in FIG. 1 except that the thermometer 26 is deleted and, instead, the thermoelectric conversion system 60 which will later be described is provided. Accordingly, the same reference numerals are assigned to constituent elements similar in function to those illustrated in FIG. 1 and description thereof will be omitted for the sake of simplification of the description. In FIG. 4, illustration of the ignition device 24 is omitted.

The gas turbine combustor 10A has the combustion gas as the heat source and comprises the combustor liner barrel 14 as the support 50. The combustor liner barrel 14 has an inner wall surface 14a and an outer wall surface 14b. The combustion gas (heat source) is covered with the inner wall surface 14a of the combustor liner barrel 14. On the other hand, the compressed air passes through the annular passage 20 which is surrounded by the outer wall surface 14b of the combustor liner barrel 14 and the casing 12.

As described above, the inner wall surface 14a and the outer wall surface 14b of the combustor liner barrel 14 correspond to the first surface 50a and the second surface 50b of the support 50, respectively.

The illustrated thermoelectric conversion system 60 is disposed on the outer wall surface 14b of the combustor liner barrel (support) 14 which covers the combustion gas (heat source).

As shown in FIG. 5, the thermoelectric conversion system 60 comprises a magnetic thermoelectric conversion element 62, which is similar in structure to the magnetic thermoelectric conversion element 40A according to the second example embodiment illustrated in FIG. 3, without filling in the respective cooling holes 28 and only around the respective cooling holes 28.

The magnetic thermoelectric conversion element 62 includes a spin Seebeck element 622 and a heat-insulation layer 624. The spin Seebeck element 622 comprises a combination of the magnetic body 42 and the electromotive body 44, which are shown in FIG. 3. The heat-insulation layer 624 comprises the heat-resistant metal oxide layer 46, which is shown in FIG. 3.

As shown in FIG. 4, the magnetic thermoelectric conversion element 62 is processed into the shape of a folded belt on the outer wall surface 14b of the combustor liner barrel 14.

The diffuser 16 has a flange portion 162 along an outer perimeter of the fuel injection nozzle 22. The flange portion 162 of the diffuser 16 is provided with connecting electrodes 64. The spin Seebeck element 622 has wirings (wirings 48 in FIG. 3) which are connected to the connecting electrodes 64. Heat-resistant electric wires 66 are connected to the connecting electrodes 64.

Accordingly, a combination of the connecting electrodes 64 and the heat-resistant electric wires 66 serves as a collecting means (64, 66) for collecting, via the wirings, electrical signals which are obtained by thermoelectric conversion in the spin Seebeck element 622.

As described above, the magnetic thermoelectric conversion element 62 has a very small mounting area as compared with a surface area of a whole of the combustor liner barrel 14, and has a thin film structure which does not inhibit the cooling flow. Therefore, by laying the magnetic thermoelectric conversion element 62 on the outer wall surface 14b of the combustor liner barrel 14, it is possible to sense temperatures over the whole of the combustor liner barrel 14 although slight loss in cooling efficiency is caused to occur.

Accordingly, if any of the plurality of cooling holes 28 is blocked during operation of the gas turbine combustor 10A, a surrounding temperature around the blocked cooling hole 28 rises. The rise in surrounding temperature results in a change in spin Seebeck electromotive force of the spin Seebeck element 622. By collecting the change in spin Seebeck electromotive force by the above-mentioned collecting means (64, 66) via the wirings (a part of the belts), it is possible to detect occurrence of clogging in the cooling hole 28.

As described above, by detecting the change in spin Seebeck electromotive force in the part of belts of the magnetic thermoelectric conversion element 62, it is possible to detect occurrence of clogging in the cooling hole 28. In addition, by detecting the change in spin Seebeck electromotive force in all belts of the magnetic thermoelectric conversion element 62, it is possible to detect abnormal combustion in the gas turbine combustor 10A.

Furthermore, by detecting the change in spin Seebeck electromotive force in the part of belts of the magnetic thermoelectric conversion element 62, it is also possible to detect, although indirectly, separation of the heat-resistant coat 30 (see FIG. 1) which is provided on the inner wall surface 14a of the combustor liner barrel 14. This is because, if the heat-resistant coat 30 is separated, a temperature at a separated spot rises and a change in spin Seebeck electromotive force occurs in the spin Seebeck element 622 of the magnetic thermoelectric conversion element 62 that is provided in the vicinity of the separated spot.

The surface temperature of the combustor liner barrel 14 rises toward a rear part of a flow of the combustion gas. As a result, it is supposed that an amount of temperature change is different depending on a position where the cooling hole 28 is blocked up. Accordingly, measured data collected and obtained by the collecting means (64, 66) is preliminarily stored as reference data so that, by comparing the reference data with current (actual) measured data, it is possible to identify a position where clogging in the cooling hole 28 occurs.

### Example 1

FIG. 6 is a plan view for illustrating a schematic configuration of a temperature distribution detection device 70 according to a first example of the present invention.

The illustrated temperature distribution detection device 70 is a device for detecting a temperature distribution of a member (support) 50 using the magnetic thermoelectric conversion element 40A according to the second example embodiment described above.

In FIG. 6, only a part corresponding to the function layer (42, 44) is illustrated and illustration of other components is omitted.

As shown in FIG. 6, in the temperature distribution detection device 70, in order to measure a distribution of temperature differences generated in the member (support) 50, the metal layer (electromotive body) 44 is deposited, on the magnetic insulator layer (magnetic layer) 42, in a state where it is patterned into a grid-like shape. The metal layer (electromotive body) 44 patterned into the grid-like shape is connected to measurement electrodes (not shown) at an end portion of the member (support) 50.

Accordingly, by measuring voltages at the respective measurement electrodes, the temperature distribution detection device 70 can measure voltages (spin Seebeck voltages) due to the spin Seebeck effect. In order to extract the spin Seebeck voltages in both of longitudinal and transversal directions of the grid, the temperature distribution detection device 70 is designed so that a direction of magnetization M of the magnetic insulator layer (magnetic body) 42 is not parallel to either of the longitudinal and the transversal directions of the grid, as illustrated in a thick-line arrow in FIG. 6. By carrying out this measurement for each position, the temperature distribution detection device 70 can measure the temperature difference distribution of the member (support) 50 and, in particular, can identify the spot where a temperature difference occurs than in the surroundings.

Alternatively, it is possible to independently dispose those elements connected to longitudinal wirings of the grid and those elements connected to transversal wirings thereof. In this event, the direction of magnetization M of the magnetic insulator layer (magnetic body) 42 can be arranged to be orthogonal to directions in which the respective wirings extend.

### Example 2

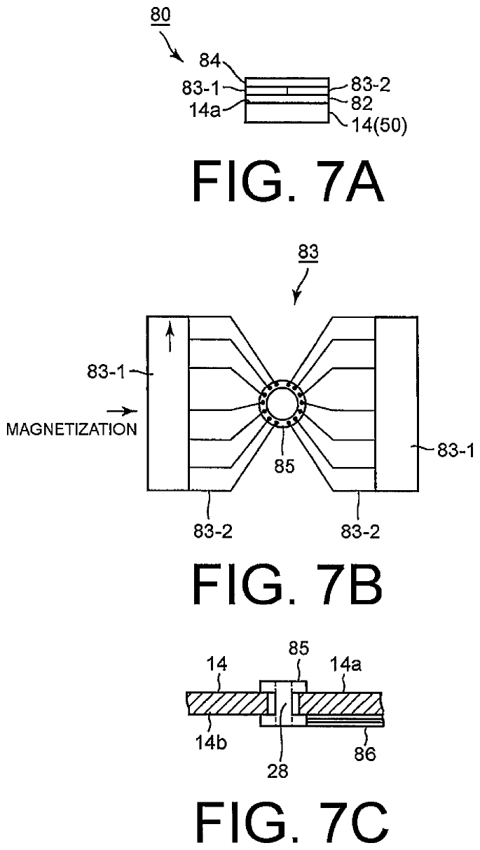

FIGS. 7A, 7B, and 7C are a fragmentary cross-sectional view, a schematic plan view, and a fragmentary cross-sectional view, respectively, which is for illustrating a schematic configuration of a temperature distribution detection device 80 according to a second example of the present invention.

The illustrated temperature distribution detection device 80 is a device for detecting a temperature distribution of the combustor liner barrel 14 by applying the magnetic thermoelectric conversion element 40 according to the first example embodiment (first modification) described above to the gas turbine combustor 10 (see FIG. 1).

Accordingly, the temperature distribution detection device 80 comprises a functional coating (which will later be described) provided on the inner wall surface 14a of the combustor liner barrel 14. The functional coating is an element which corresponds to the magnetic thermoelectric conversion element 40 illustrated in FIG. 2.

As shown in FIG. 7A, the functional coating comprises an insulation layer 82, an electrode layer 83, a magnetic layer 84, and a top layer (not shown). The insulation layer 82 corresponds to the contact layer 52 in FIG. 2. The electrode layer 83 corresponds to the electromotive body 44 in FIG. 2. The magnetic layer 84 corresponds to the magnetic body 42 in FIG. 2. The top layer, which is not shown, corresponds to the heat-resistant metal oxide film 46 in FIG. 2.

The combustor liner barrel 14 comprises a heat-resistant base material. The heat-resistant base material 14 is a base material for maintaining a shape of the liner, and is formed of metal or ceramics which is guaranteed to have a rigidity even at an operation temperature of the gas turbine combustor 10. The heat-resistant base material 14 is of a cylindrical shape and has a number of cooling holes 28 (see FIG. 1) in the wall surface thereof.

The heat-resistant base material 14 is divided into a high-temperature portion which is in contact with the combustion gas and a low-temperature portion which is in contact with the cooling air. In the example being illustrated, directly on the high-temperature portion, the insulation layer 82, the electrode layer 83, the magnetic layer 84, and the top layer (not shown) are formed in this order in a layered structure.

In a case where the magnetic layer comprises an insulator, on the high-temperature portion, the magnetic layer 84, the electrode layer 83, and the top layer (not shown) are formed in this order in a layered structure.

The insulation layer 82 is made of a material for insulating the heat-resistant base material 14 and the electrode layer 83, for example, ceramics. In a case where the heat-resistant base material 14 has no conductivity, the insulation layer 82 may be omitted.

The electrode layer 83 forms the spin Seebeck element by being bonded to the magnetic layer 84. The electrode layer 83 comprises signal layers 83-1 for producing signals proportional to a heat flow and wiring layers 83-2 for propagating the signals.

FIG. 7B shows an example of configuration of the electrode layer 83. Although a number of on-line detection structures are arranged in FIG. 7B, a lattice-shaped arrangement may be adopted.

The signal layers 83-1 may be made of a material having a spin current/electric current conversion function. The signal layers 83-1 produce voltages proportional to the heat flow. In addition, in order to calculate a resistance due to the electromotive force caused by application of the electric current and to measure a temperature of the signal layers 83-1 from the resistance, the signal layers 83-1 desirably have temperature dependency of a resistance value.

The temperature distribution detection device 80 further comprises a wiring portion 86 and a measurement portion (not shown).

As shown in FIGS. 7B and 7C, the wiring layers 83-2 provide a connecting means to the wiring portion 86 for extracting sensor outputs generated by the signal layers 83-1 via a multipolar connector 85 to the outside. As shown in FIG. 7C, the multipolar connector 85 is inserted and provided in the cooling hole 28 (see FIG. 1).

Inasmuch as the sensor outputs in the signal layers 83-1 are sent to the measurement portion (not shown) through the wiring portion 86, external electromotive forces in the wiring layers 83-2 and the wiring portion 86 are required to be small as compared with electromotive forces of the sensor outputs. The main external electromotive force in the signal layers 83-1 is exemplified by a spin Seebeck voltage. Therefore, the most desirable configuration as the wiring layers 83-2 is a material of the same kind as the material constituting the signal layers 83-1 or a material having the Seebeck coefficient equivalent thereto.

In addition, in order to avoid spin Seebeck outputs in the wiring layers 83-2, the material constituting the wiring layers 83-2 is required to have a sufficiently small spin/electric current conversion efficiency or to have a composite structure with a spin insulator formed on a contact surface with the magnetic layer 84. The spin insulator is made of a material which is not the magnetic insulator, for example, Al₂O₃ or SiO₂, and is required to have a thickness of 1 nm or more.

As shown in FIGS. 7B and 7C, a mode of connection between the wiring layers 83-2 and the wiring portion 86 is the multipolar connector 85 in the cooling hole 28 in the heat-resistant base material 14. In this event, in order to remove the above-mentioned spin Seebeck voltages, a thermal anchor is desirably provided.

The top layer, which is not shown, is a thermal barrier layer which is designed so that the magnetic layer 84 is kept at an operable temperature not higher than the Curie temperature.

Although a wiring in the wiring portion 86 is a cable which is disposed to pass through an outer periphery of the combustor liner barrel 14, the wiring may be directly formed on the heat-resistant base material 14. In view of prevention of the external electromotive force, it is required to secure the thermal anchor at a connection portion between the wiring portion 86 and the measurement portion (not shown).

It is sufficient that the measurement portion, which is not shown, can measure a direct current electromotive force. In addition, in order to detect the temperature as well as the heat flow, the measurement portion is required to have an electric current application function and to be able to measure a voltage on application of the electric current. In this case, it is desirable that a positive electric current and a negative electric current can be applied as the electric current. Assuming that I represents an electric current value and V represents a voltage value, a resistance value R is calculated by:

R=[V(+I)+V(4)]/I/2,

and, simultaneously, the spin Seebeck electromotive force V_{SSE} proportional to the heat flow is measurable by:

V_{SSE}=[V(+I)V(−I)]/2.

From this, simultaneous measurement can be implemented by making the measurement portion have a function of switching+I and −I at a certain frequency and of measuring an AC voltage and a DC voltage. Although the higher frequency is better, the frequency may be lowered in conformity with a time scale of a necessary sensor signal.

Taking resistance measurement into account, the wiring layers 83-2 are desired to have a low resistance and are desired to be a good conductor or to be thick so as to have a resistance which is sufficiently smaller than that of the signal layers 83-1. In addition, a four-wire resistance measurement may be used by duplicating the wires formed by the wiring layers 83-2 or the four-wire resistance measurement may be carried out by using four adjacent wires.

The measurement portion is required to be able to measure the voltages which are equal in number to spots to be measured. Therefore, as the measurement portion, the same number of voltmeters may be prepared or measurement may be made by switching by means of relay terminals.

The temperature distribution detection device 80 according to the second example provides a means capable of measuring the heat flows and the temperatures at any desired points in the above-mentioned manner. It is possible to estimate a distribution inside a cylinder from spatial and temporal values at a number of points in accordance with a thermal diffusion equation. In addition, depending on a purpose of measurement, it is possible to optimize suitable measurement spots and structure.

### Example 3

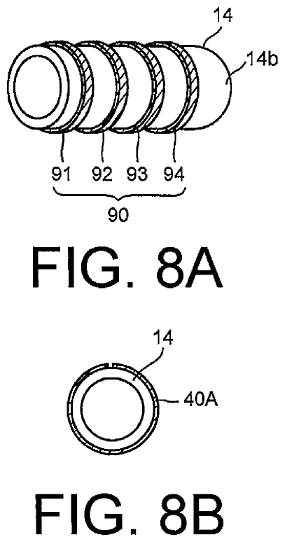

FIGS. 8A and 8B are a schematic perspective view and a cross-sectional view, respectively, which is for illustrating a schematic configuration of a temperature distribution detection device 90 according to a third example of the present invention.

The illustrated temperature distribution detection device 90 is a device for detecting a temperature distribution of the combustor liner barrel 14 by applying the magnetic thermoelectric conversion element 40A according to the second example embodiment described above to the gas turbine combustor 10 (see FIG. 1).

Accordingly, the temperature distribution detection device 90 comprises first through fourth sensors 91, 92, 93, and 94 which are provided on the outer wall surface 14b of the combustor liner barrel 14. The first through the fourth sensors 91 to 94 are disposed on the outer wall surface 14b of the combustor liner barrel 14 at positions shifted from one another, as shown in FIG. 8A. Although the number of the sensors is four in the example being illustrated, it is a matter of course that the present invention is not limited thereto. That is, any number may be selected as the number of the sensors.

As shown in FIG. 8B, each of the first through the fourth sensors 91 to 94 comprises the magnetic thermoelectric conversion element 40A illustrated in FIG. 3.

The illustrated temperature distribution detection device 90 can increase an accuracy toward a high-speed measurement by increasing a signal strength by measuring the heat flow values and the temperatures which are leveled along the circumference of the combustor liner barrel 14.

Herein, it is assumed that r represents a radius of the cylinder of the combustor liner barrel 14, λ, represents an experimental parameter reflecting a thermal conductivity of the interior of the cylinder, jq represents a measured heat flow, and To represents a measured temperature. In this event, a temperature T at a central part of the cylinder is given by T=To+jqr/λ. By detecting first through fourth temperatures T₉₁, T₉₂, T₉₃, and T₉₄ in the first through the fourth sensors 91 to 94 which are disposed at the positions shifted from one another, it is possible to monitor a spatial profile. In addition, by calculating a delay at each temperature as a function of time, the temperature distribution detection device 90 can estimate a flow rate when the combustion temperature oscillates. Furthermore, the temperature distribution detection device 90 can detect formation of a turbulent flow and ignition failure.

While the present invention has been particularly shown and described with reference to the example embodiments and examples thereof, the present invention is not limited to the example embodiments and the examples mentioned above. It will be understood by those of ordinary skill in the art that various changes in configuration and details may be made within the scope of the present invention.

A part or a whole of the example embodiments and examples described above may be described as, but not limited to, the following supplementary notes.

(Supplementary Note 1) A magnetic thermoelectric conversion element which is provided on a surface of a support in contact with a heat source, the magnetic thermoelectric conversion element comprising:

a magnetic body;

an electromotive body which is magnetically coupled to the magnetic body and which has an electrical conductivity; and

a heat-resistant metal oxide film configured to cover the magnetic body and the electromotive body.

(Supplementary Note 2) The magnetic thermoelectric conversion element according to Supplementary Note 1, wherein the heat-resistant metal oxide film has a thermal conductivity which is not more than 10 [W/mK].

(Supplementary Note 3)

The magnetic thermoelectric conversion element according to Supplementary Note 1 or 2, wherein the heat-resistant metal oxide film has a heat-transfer coefficient which is not more than 10⁴ [W/m²K].

(Supplementary Note 4)

The magnetic thermoelectric conversion element according to any one of Supplementary Notes 1 to 3,

wherein the magnetic thermoelectric conversion element is provided on an inner wall surface of the support,

wherein the heat-resistant metal oxide film has an interface being in contact with the heat source kept at or above a temperature (Curie temperature) at which the magnetic body loses magnetism.

(Supplementary Note 5)

The magnetic thermoelectric conversion element according to any one of Supplementary Notes 1 to 3,

wherein the magnetic thermoelectric conversion element is provided on an outer wall surface of the support,

wherein the heat-resistant metal oxide film has an interface being, via the support, in contact with the heat source kept at or above a temperature (Curie temperature) at which the magnetic body loses magnetism.

(Supplementary Note 6)

A thermoelectric conversion system which is provided on a surface of a support in contact with a heat source, the thermoelectric conversion system comprising:

at least one magnetic thermoelectric conversion element which is disposed at a predetermined position of the support, the magnetic thermoelectric conversion element comprising a magnetic body and an electromotive body which is magnetically coupled to the magnetic body; and a means configured to collect, via wirings electrically connected to the electromotive body, electrical signals which are obtained by thermoelectric conversion, wherein the magnetic thermoelectric conversion element and the wirings are covered by a heat-resistant metal oxide film.

(Supplementary Note 7) The thermoelectric conversion system according to Supplementary Note 6, wherein the electromotive body and the wirings are formed by the same material.

(Supplementary Note 8) The thermoelectric conversion system according to Supplementary Note 6 or 7, wherein the heat-resistant metal oxide film has a thermal conductivity which is not more than 10 [W/mK].

(Supplementary Note 9)

The thermoelectric conversion system according to any one of Supplementary Notes 6 to 8, wherein the heat-resistant metal oxide film has a heat-transfer coefficient which is not more than 10⁴ [W/m²K].

(Supplementary Note 10)

The thermoelectric conversion system according to any one of Supplementary Notes 6 to 9, wherein the thermoelectric conversion system is provided on an inner wall surface of the support, wherein the heat-resistant metal oxide film has an interface being in contact with the heat source kept at or above a temperature (Curie temperature) at which the magnetic body loses magnetism.

(Supplementary Note 11)

The thermoelectric conversion system according to any one of Supplementary Notes 6 to 9, wherein the magnetic thermoelectric conversion element is provided on an outer wall surface of the support, wherein the heat-resistant metal oxide film has an interface being, via the support, in contact with the heat source kept at or above a temperature (Curie temperature) at which the magnetic body loses magnetism.

(Supplementary Note 12)

A hot-gas path member which has an inner surface in contact with a hot gas and an outer surface in contact with a cooling flow, the hot-gas path member comprising:

a magnetic layer formed on the outer surface;

a metal layer which is overlapped on the magnetic layer and which is in contact with the cooling flow; and

measurement wires which are disposed from the metal layer along the outer surface.

This application is based upon and claims the benefit of priority from Japanese patent application No. 2017-237459, filed on Dec. 12, 2017, the disclosure of which is incorporated herein in its entirety by reference.

### REFERENCE SIGNS LIST

10, 10A: combustor (gas turbine combustor)
12: housing (casing; outer barrel)
14: combustion tube (combustor liner barrel; heat-resistant base material)
14a: inner wall surface
14b: outer wall surface
16: diffuser
162: flange portion
18: combustion chamber
20: annular passage
22: fuel injection nozzle
24: ignition device
26: thermometer
28: cooling hole
30: heat-resistant coat (thermal heat-shielding coating)
40, 40A: magnetic thermoelectric conversion element
42: magnetic body (magnetic insulator layer; magnetic metal layer;
magnetic layer)
44: electromotive body (metal layer)
46: heat-resistant metal oxide film
48: wiring (measurement wire)
50: support
50a: first surface
50b: second surface
52: contact layer
522: diffused layer
524: bonding layer
54: surface protection layer
60: thermoelectric conversion system
62: magnetic thermoelectric conversion element
622: spin Seebeck element
624: heat-insulation layer
64: connecting electrode
66: heat-resistant electric wire
70: temperature distribution detection device
80: temperature distribution detection device
82: insulation layer
83: electrode layer
83-1: signal layer
83-2: wiring layer
84: magnetic layer
85: multipolar connector
86: wiring portion
90: temperature distribution detection device
91˜94: sensor

1. A magnetic thermoelectric conversion element which is provided on a surface of a support in contact with a heat source, the magnetic thermoelectric conversion element comprising:
a magnetic body;
an electromotive body which is magnetically coupled to the magnetic body and which has an electrical conductivity; and
a heat-resistant metal oxide film configured to cover the magnetic body and the electromotive body.

2. The magnetic thermoelectric conversion element as claimed in claim 1, wherein the heat-resistant metal oxide film has a thermal conductivity which is not more than 10 [W/mK].

3. The magnetic thermoelectric conversion element as claimed in claim 1, wherein the heat-resistant metal oxide film has a heat-transfer coefficient which is not more than 10⁴ [W/m²K].

4. The magnetic thermoelectric conversion element as claimed in claim 1,
wherein the magnetic thermoelectric conversion element is provided on an inner wall surface of the support,
wherein the heat-resistant metal oxide film has an interface being in contact with the heat source kept at or above a temperature (Curie temperature) at which the magnetic body loses magnetism.

5. The magnetic thermoelectric conversion element as claimed in claim 1,
wherein the magnetic thermoelectric conversion element is provided on an outer wall surface of the support,
wherein the heat-resistant metal oxide film has an interface being, via the support, in contact with the heat source kept at or above a temperature (Curie temperature) at which the magnetic body loses magnetism.

6. A thermoelectric conversion system which is provided on a surface of a support in contact with a heat source, the thermoelectric conversion system comprising:
at least one magnetic thermoelectric conversion element which is disposed at a predetermined position of the support, the magnetic thermoelectric conversion element comprising a magnetic body and an electromotive body which is magnetically coupled to the magnetic body; and
a means configured to collect, via wirings electrically connected to the electromotive body, electrical signals which are obtained by thermoelectric conversion,
wherein the magnetic thermoelectric conversion element and the wirings are covered by a heat-resistant metal oxide film.

7. The thermoelectric conversion system as claimed in claim 6, wherein the electromotive body and the wirings are formed by the same material.

8. The thermoelectric conversion system as claimed in claim 6, wherein the heat-resistant metal oxide film has a thermal conductivity which is not more than 10 [W/mK].

9. The thermoelectric conversion system as claimed in claim 6, wherein the heat-resistant metal oxide film has a heat-transfer coefficient which is not more than 10⁴ [W/m²K].

10. The thermoelectric conversion system as claimed in claim 6,
wherein the thermoelectric conversion system is provided on an inner wall surface of the support,
wherein the heat-resistant metal oxide film has an interface being in contact with the heat source kept at or above a temperature (Curie temperature) at which the magnetic body loses magnetism.

11. The thermoelectric conversion system as claimed in claim 6,
wherein the magnetic thermoelectric conversion element is provided on an outer wall surface of the support,
wherein the heat-resistant metal oxide film has an interface being, via the support, in contact with the heat source kept at or above a temperature (Curie temperature) at which the magnetic body loses magnetism.

12. A hot-gas path member which has an inner surface in contact with a hot gas and an outer surface in contact with a cooling flow, the hot-gas path member comprising:
a magnetic layer formed on the outer surface;
a metal layer which is overlapped on the magnetic layer and which is in contact with the cooling flow; and
measurement wires which are disposed from the metal layer along the outer surface.
